(19) United States
(12) Patent Application Publication
(10) Pub. No.: US 2013/0167906 A1
(43) Pub. Date: Jul. 4, 2013

(54) ORGANIC PHOTOVOLTAIC MODULE

(71) Applicants: Mei-Ju Lee, Kaohsiung City (TW); Chao-Feng Sung, Hsinchu City (TW)

(72) Inventors: Mei-Ju Lee, Kaohsiung City (TW); Chao-Feng Sung, Hsinchu City (TW)

(73) Assignee: INDUSTRIAL TECHNOLOGY RESEARCH INSTITUTE, HSINCHU (TW)

(21) Appl. No.: 13/478,066

(22) Filed: May 22, 2012

(30) Foreign Application Priority Data
Dec. 29, 2011 (TW) TW100149456

(51) Int. Cl. H01L 51/44; H01L 51/48

(52) U.S. Cl. 136/249; 438/80; 438/4; 257/E51.012

(57) ABSTRACT

An organic photovoltaic module is disclosed, including a plurality of devices, wherein neighboring devices are separated by a gap, and each of the devices include a bottom electrode, a first carrier transporting layer, an active layer, a second carrier transporting layer and a top electrode. An insulating layer is disposed on the devices and filled into the gap, wherein the insulating layer includes a first opening exposing the bottom electrode and a second opening exposing the top electrode. A metal trace layer is filled into the first opening and the second opening to connect the devices in series or in parallel.

### CROSS-REFERENCE TO RELATED APPLICATION

This application claims priority of Taiwan Patent Application No. 100149456, filed on Dec. 29, 2011, the entirety of which is incorporated by reference herein.

### BACKGROUND

1. Technical Field

The present disclosure relates generally to a solar cell module and more particularly to an organic photovoltaic module and fabrication and repair methods thereof.

2. Description of the Related Art

Organic photovoltaics are more and more popular because they are simple to fabricate, light weight, have a low cost and have bendable characteristics. In addition, an organic photovoltaic can be integrated into a roll to roll apparatus, such that it is easier to be fabricated with a large size than other solar cells. Currently, organic photovoltaics can be connected in series or in parallel to increase cell efficiency.

FIG. 1A˜FIG. 1E shows immediate stages of a method for forming a series connected organic photovoltaic module. Referring to FIG. 1A, a substrate 102 is provided, and a plurality of bottom electrodes 104 are formed on the substrate 102. Referring to FIG. 1B, an electron transporting layer 106 is formed on each of the bottom electrodes 104. Referring to FIG. 1C, an active layer 108 is formed on the electron transporting layer 106. Referring to FIG. 1D, a hole transporting layer 110 is formed on the active layer 108. Referring to FIG. 1E, a top electrode 112 is formed on the hole transporting layer 110 to series connect bottom electrodes 104 of neighboring organic photovoltaics. However, the non-active area (the area A shown in FIG. 1E) of the conventional organic photovoltaic module is too large. Thus, overall coverage ratio of the organic photovoltaic module is affected and overall output energy and efficiency of the solar cell module are further affected. Furthermore, design flexibility of the organic photovoltaic module is not satisfactory. When one of the cells fails, voltage or current of the overall organic photovoltaic module is affected.

### SUMMARY

An embodiment provides an organic photovoltaic module, comprising a plurality of devices, wherein neighboring devices are separated by a gap, and each of the devices comprise a bottom electrode, a first carrier transporting layer, an active layer, a second carrier transporting layer and a top electrode. An insulating layer is disposed on the devices and filled into the gap, wherein the insulating layer comprises a first opening exposing the bottom electrode and a second opening exposing the top electrode. A metal trace layer is filled into the first opening and the second opening to connect the devices in series or in parallel.

Another embodiment provides a method for forming an organic photovoltaic module, comprising: providing a substrate; forming a plurality of bottom electrodes on the substrate; forming a first carrier transporting layer on the bottom electrodes and the substrate; forming an active layer on the first carrier transporting layer; forming a second carrier transporting layer on the active layer; forming a top electrode layer on the second carrier transporting layer and patterning the top electrode layer to form a plurality of top electrodes; performing a patterning process to the first carrier transporting layer, the active layer and the second carrier transporting layer to form a plurality of devices, wherein neighboring devices are separated by a gap; forming an insulating layer on the device and filled into the gap, wherein the insulating layer comprises a first opening exposing the bottom electrode and a second opening exposing the top electrode; and forming a metal trace layer to be filled into the first opening and the second opening to connect the devices in series or in parallel.

Another embodiment provides a method for repairing an organic photovoltaic module, comprising: providing an organic photovoltaic module, comprising: a plurality of devices, wherein neighboring devices are separated by a gap, and each of the devices comprise a bottom electrode, a first carrier transporting layer, an active layer, a second carrier transporting layer and a top electrode; an insulating layer disposed on the devices and filled into the gap, wherein the insulating layer comprises a first opening exposing the bottom electrode and a second opening exposing the top electrode; and a metal trace layer filled into the first opening and the second opening to connect the devices in series or in parallel, wherein when one of the devices fails, a knife or laser is used to cut the metal trace layer in the first opening or the second opening of the failed device for the organic photovoltaic module to bypass the failed device to repair the organic photovoltaic module.

### BRIEF DESCRIPTION OF DRAWINGS

The disclosure can be more fully understood by reading the subsequent detailed description and examples with references made to the accompanying drawings, wherein,

FIG. 1A˜FIG. 1E shows immediate stages of a method for forming a series connected organic photovoltaic module.

FIG. 2A shows a plan view of an immediate stage for forming an organic photovoltaic module in accordance with an embodiment of the disclosure.

FIG. 2B shows a cross section along line I-I′ of FIG. 2A.

FIG. 3A shows a plan view of an immediate stage for forming an organic photovoltaic module in accordance with an embodiment of the disclosure.

FIG. 3B shows a cross section along line I-I′ of FIG. 3A.

FIG. 4A shows a plan view of an immediate stage for forming an organic photovoltaic module in accordance with an embodiment of the disclosure.

FIG. 4B shows a cross section along line I-I′ of FIG. 4A.

FIG. 5A shows a plan view of an immediate stage for forming an organic photovoltaic module in accordance with an embodiment of the disclosure.

FIG. 5B shows a cross section along line I-I′ of FIG. 5A.

FIG. 6A shows a plan view of an immediate stage for forming an organic photovoltaic module in accordance with an embodiment of the disclosure.

FIG. 6B shows a cross section along line I-I′ of FIG. 6A.

FIG. 7A shows a plan view of an immediate stage for forming an organic photovoltaic module in accordance with an embodiment of the disclosure.

FIG. 7B shows a cross section along line I-I′ of FIG. 7A.

FIG. 8A shows a plan view of an immediate stage for forming an organic photovoltaic module in accordance with an embodiment of the disclosure.

FIG. 8B shows a cross section along line I-I′ of FIG. 8A.

FIG. 9A shows a plan view of an immediate stage for forming an organic photovoltaic module in accordance with an embodiment of the disclosure.

FIG. 9B shows a cross section along line I-I′ of FIG. 9A.

FIG. 10A shows a plan view of an immediate stage for forming an organic photovoltaic module in accordance with an embodiment of the disclosure.

FIG. 10B shows a cross section along line I-I′ of FIG. 10A.

FIG. 10C shows a cross section along line II-II′ of FIG. 10A

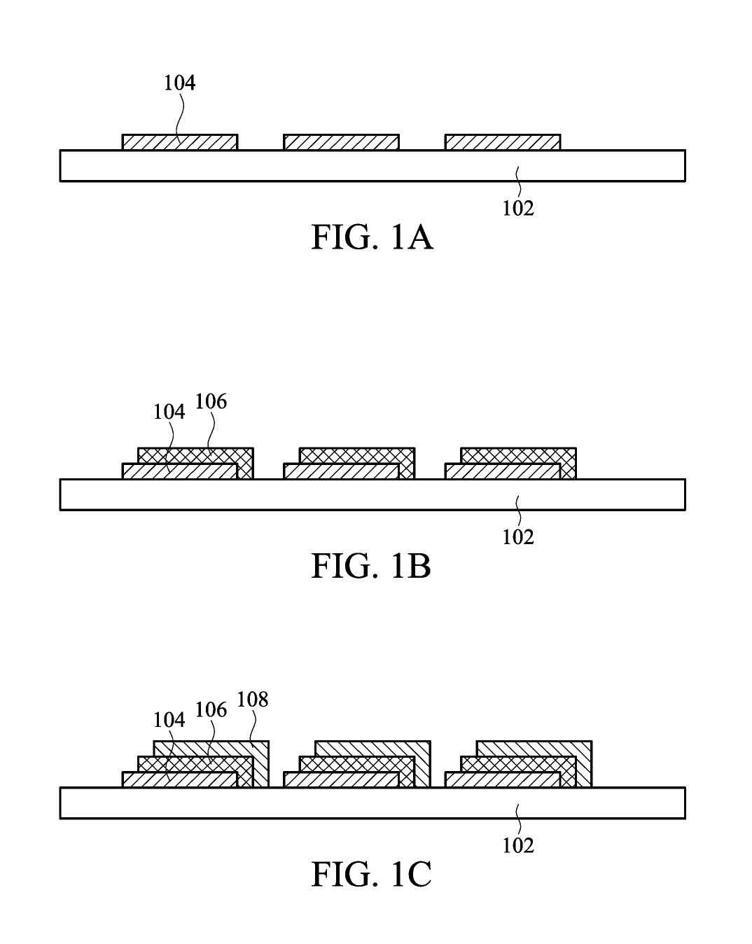

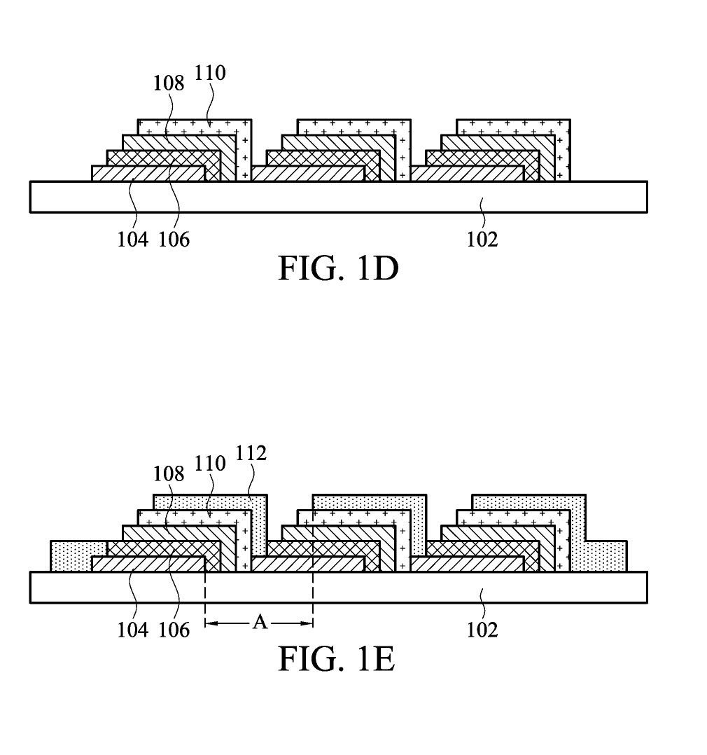

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

An object for providing an organic photovoltaic module of the disclosure is to increase effective coverage, and make series connection and parallel connection between devices easier. In the conventional technology, if some devices fail, overall devices are affected. According to the design of the back electrodes of the disclosure, failed devices can be repaired or removed by an easier way. The disclosure not only increases module coverage of large-area organic photovoltaic modules, but also can improve yield of fabrication of organic photovoltaic modules.

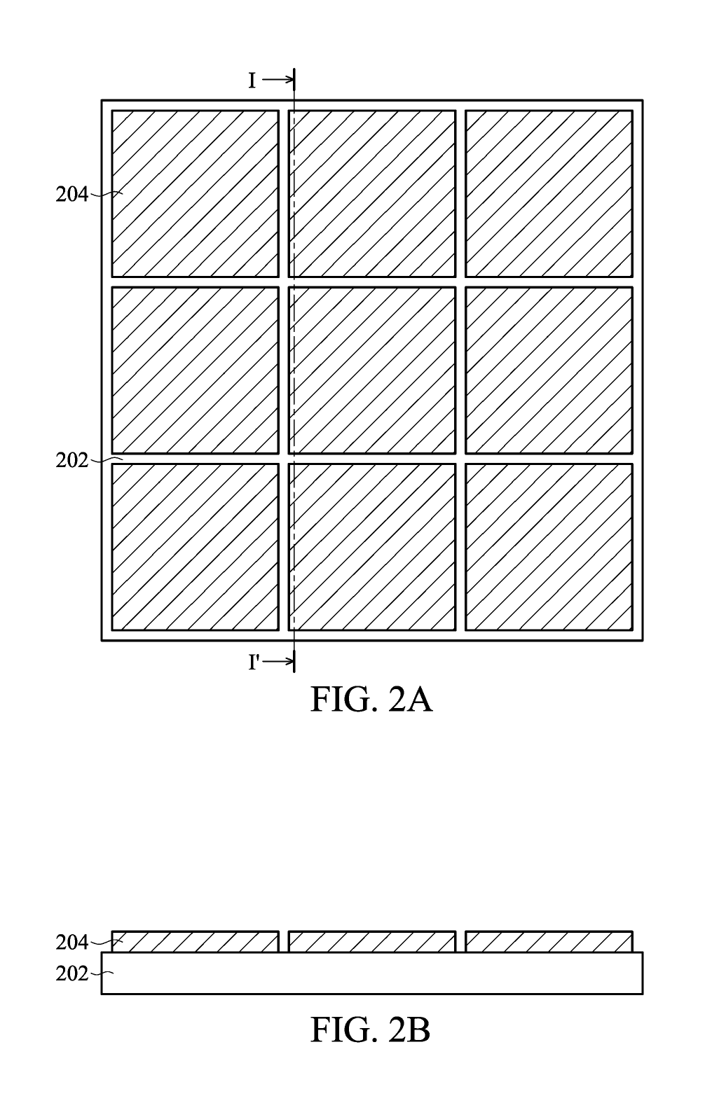

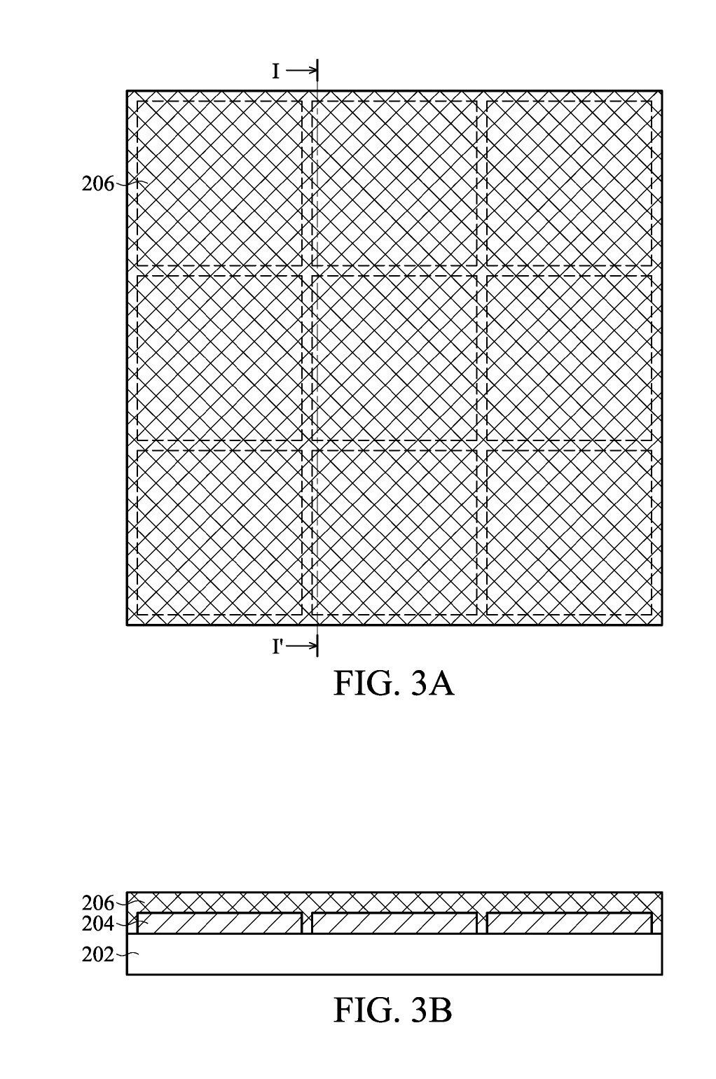

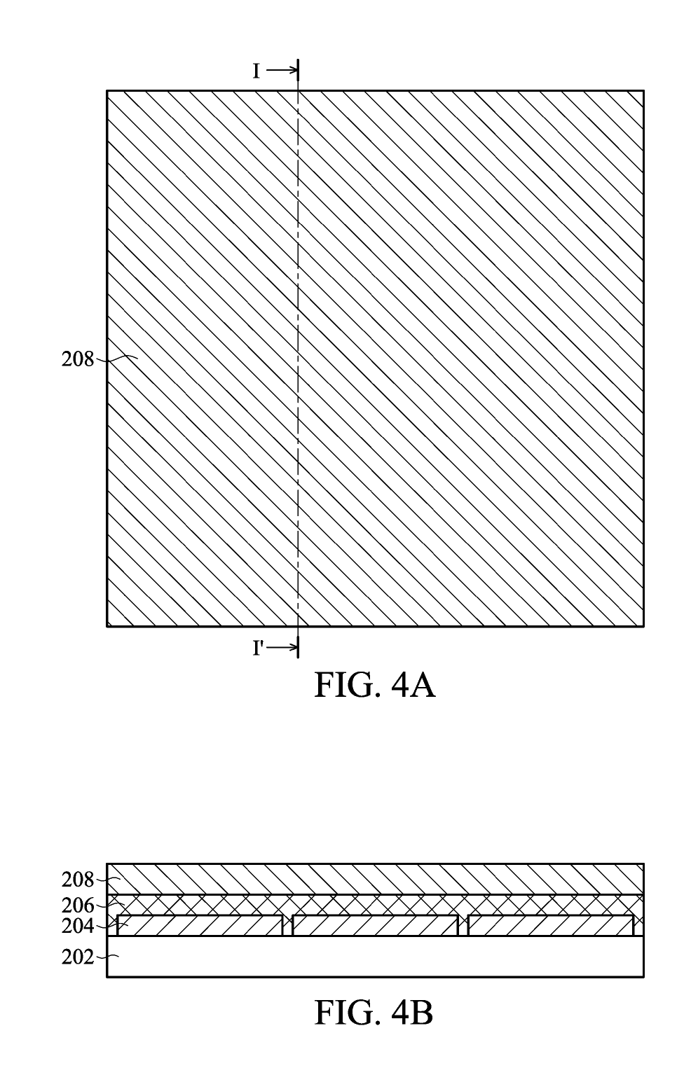

A method for forming an organic photovoltaic module of an embodiment of the disclosure is illustrated in FIG. 2A˜10C. FIG. 2A shows an organic photovoltaic module of an embodiment of the disclosure. FIG. 2B shows a cross section along line I-I′ of FIG. 2A. Referring to FIG. 2A and FIG. 2B, a substrate 202 is provided, wherein the substrate 202 can be glass or plastic. Next, a plurality of bottom electrodes 204 is formed on the substrate 202. In the embodiment of the disclosure, the method for forming the bottom electrode 204 comprises forming a transparent conductive layer, such as an ITO or IZO layer, and then an etching process is performed to pattern the transparent conductive layer for forming the bottom electrode 204. Referring to FIG. 3A and FIG. 3B, a first carrier transporting layer 206 is formed on the bottom electrode 204. In an embodiment of the disclosure, the first carrier transporting layer 206 is an electron transporting layer, such as Ca, Li, Cs₂CO₃, TiO₂, LiF or ZnO. In an another embodiment of the disclosure, the first carrier transporting layer 206 is a hole transporting layer, such as PEDOT:PSS, V₂O₅, MoO₃ or WO₃. In an embodiment of the disclosure, the method for forming the first carrier transporting layer 206 comprises spin coating, slot die coating, gravure coating or ink jet printing. Referring to FIG. 4A and FIG. 4B, an active layer 208 is formed on the first carrier transporting layer 206. In an embodiment of the disclosure, the active layer 208 is an organic bulk heterojunction optic electron convention layer, which can be a chemical compound or a mixture comprising of an organic conjugated polymer donor material and a receptor material, and covalent bonds are between the donor material and the receptor material, or the donor material contacts the receptor material. The active layer 208 can generate an excited state which can be a singlet state or a triplet state. In an embodiment which the solar cell is single-layer solar cell, the active layer 208 is composed of organic conjugated polymer or copolymer of organic donors and organic receptors. In an embodiment of the disclosure, the method for forming the active layer 208 comprises spin coating, slot die coating, gravure coating or ink jet printing.

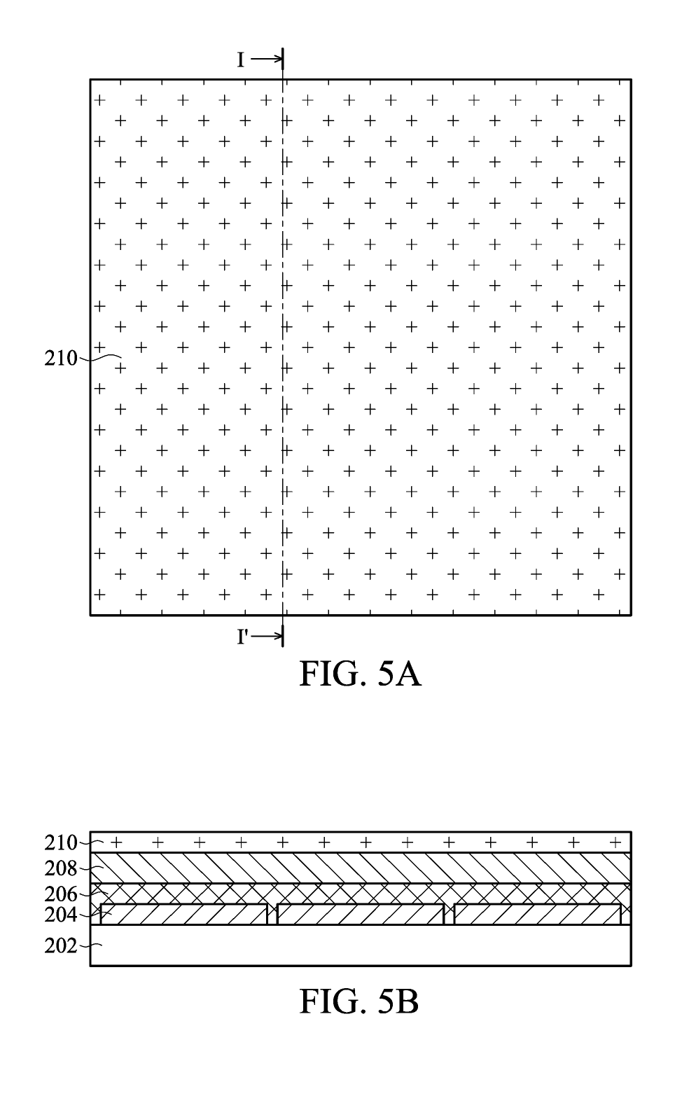

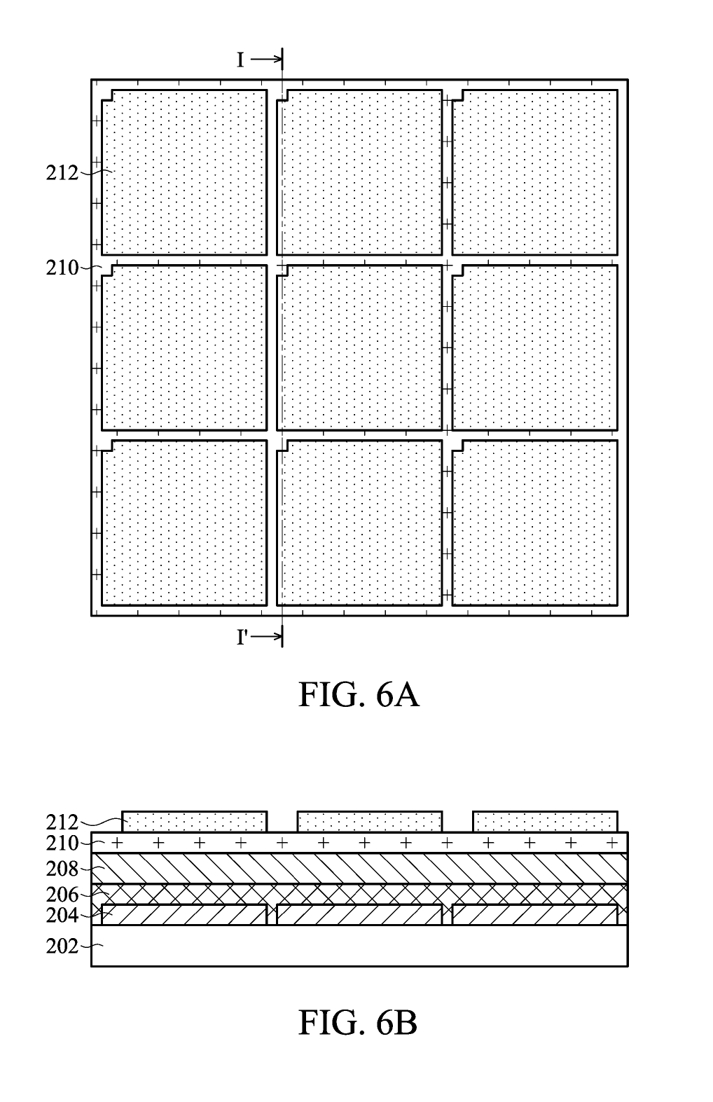

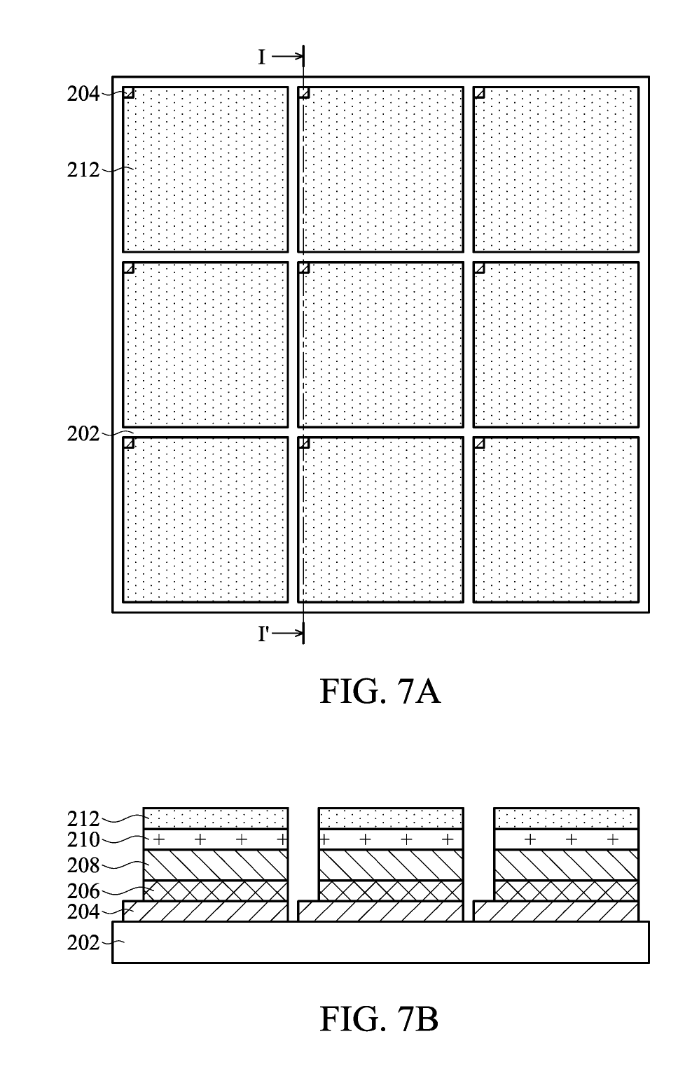

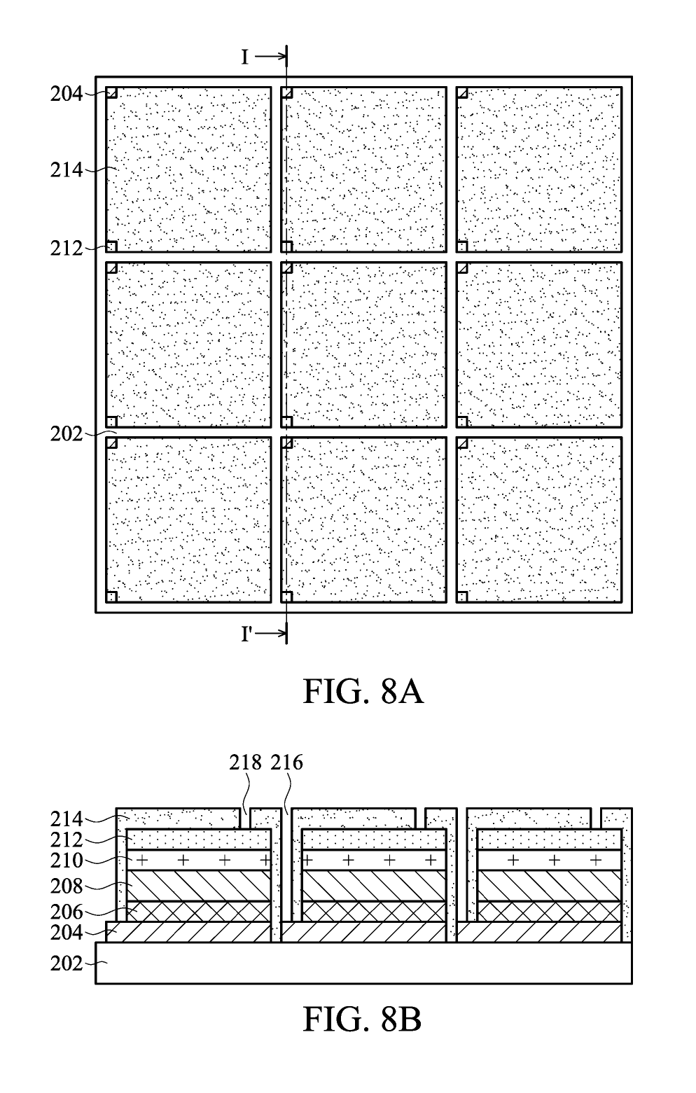

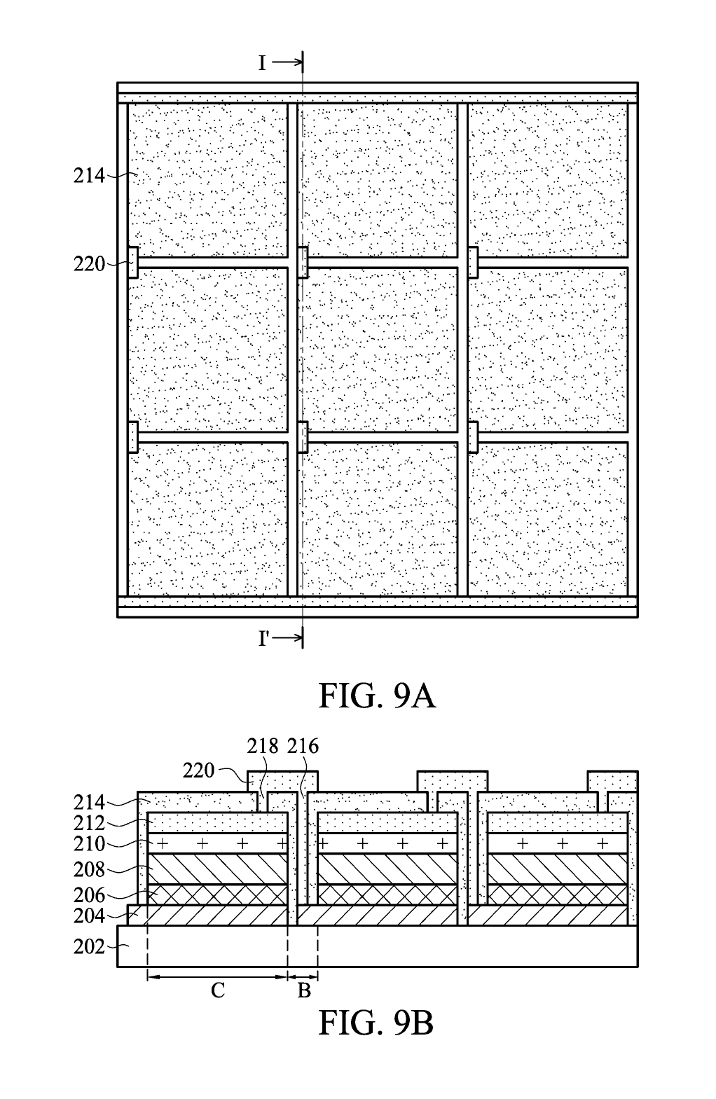

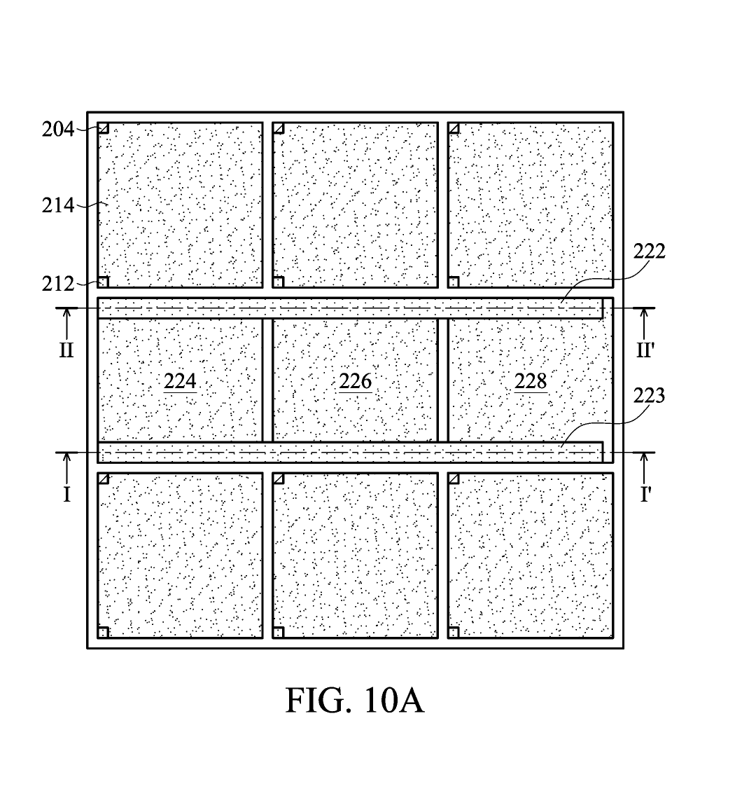

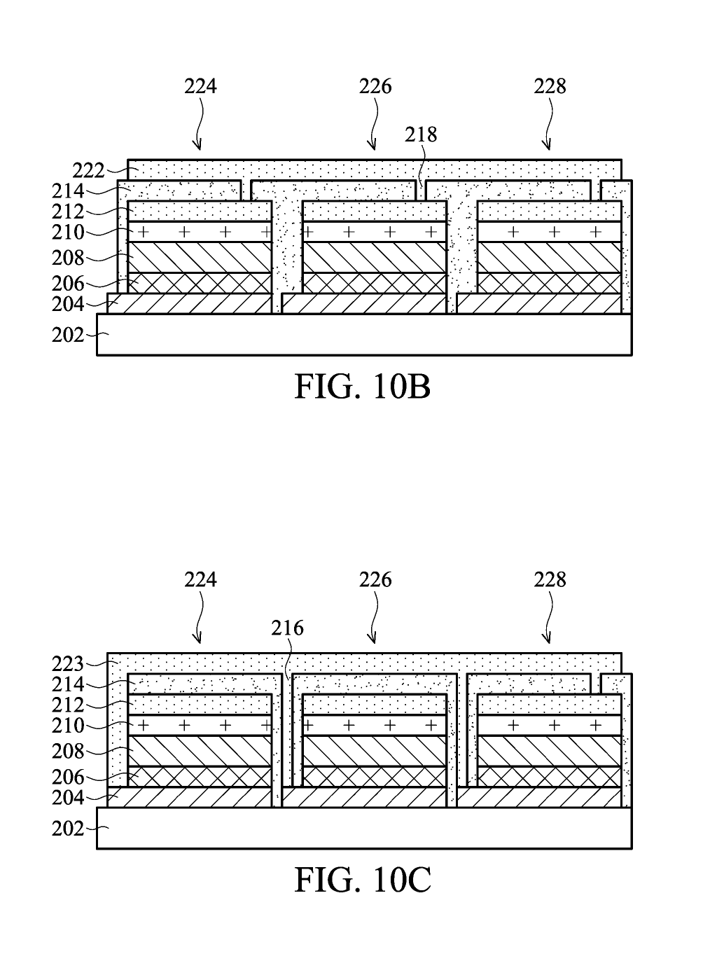

Referring to FIG. 5A and FIG. 5B, a second carrier transporting layer 210 is formed on the bottom electrode 204. In an embodiment of the disclosure, the second carrier transporting layer 210 is a hole transporting layer, such as PEDOT:PSS, V₂O₅, MoO₃ or WO₃. In a another embodiment of the disclosure, the second carrier transporting layer 210 is a electron transporting layer, such as Ca, Li, Cs₂CO₃, TiO₂, LiF or ZnO. In an embodiment of the disclosure, the method for forming the second carrier transporting layer 210 comprises spin coating, slot die coating, gravure coating or ink jet printing. Next, referring to FIG. 6A and FIG. 6B, a plurality of top electrodes 212 are formed on the second carrier transporting layer 210. In an embodiment of the disclosure, the method for forming the top electrodes 212 comprises forming a top electrode layer, for example including Ag, Al, Au or transparent conductive materials. Next, etching, laser dicing or mechanical dicing is performed to pattern the top electrode layer for forming the top electrodes 212. Thereafter, referring to FIG. 7A and FIG. 7B, a pattering process is performing the separate the devices. In an embodiment of the disclosure, the etching process can be performed to separate the devices using the top electrode 212 or a photo resist as a mask. In another embodiment of the disclosure, separating the devices can be accomplished by laser or mechanical dicing. Referring to FIG. 8A and FIG. 8B, an insulating layer 214 is formed on the top electrode 212 and filled into gaps between devices. In an embodiment of the disclosure, the insulating layer 214 comprises silicon oxide, silicon nitride or macromolecule insulating material, such as Polyvinylpyrrolidone (PVP), PolyVinyl Chloride (PVC) and the like. Next, a patterning process, such as etching, is performed to the insulating layer 214 to form a first opening 216 exposing the bottom electrode 204 and a second opening 218 exposing the top electrode 212. Referring to FIG. 9A and FIG. 9B, a metal trace layer 220 or metal traces are formed on the insulating layer 214 and are filled into the first opening 216 and the second opening 218, and as shown in FIG. 9A and FIG. 9B, the metal trace layer 220 series connects neighboring solar cells through the first opening 216 and the second opening 218. In addition, as shown in FIG. 10A, FIG. 10B and FIG. 10C (FIG. 10B shows a cross section along line I-I′ of FIG. 10A, and FIG. 10C shows a cross section along line II-II′ of FIG. 10A), the disclosure can design the first metal trace 222 to connect the top electrodes 212 of the solar cells 224, 226 and 228 in parallel at the same row through the second opening 218, or the second metal trace 223 to connect the bottom electrodes 204 of the solar cells 224, 226 and 228 in parallel at the same row through the first opening 216. Thereafter, a protective layer (not shown), such as high polymer, is formed on the first metal trace layer 222, the second metal trace layer 223 and the insulating layer 214 to protect devices and isolate moisture and oxygen.

The aforementioned organic photovoltaic module has features as follows. First, referring to FIG. 9B, the organic photovoltaic module of the disclosure can provide a non-active area B having a smaller area and an active area C having a relatively larger area. Thus, effective coverage of the organic photovoltaic module can be increased. In an embodiment of the disclosure, the active area is 85% of the total area of the organic photovoltaic module. Second, the embodiment of the disclosure can make series connection and parallel connection between devices easier through design of electrodes. Third, when some devices fail in the conventional module, efficiency of the overall module is affected. It is easier for the embodiment of the disclosure to repair or cancel failed devices. For example, referring to FIG. 10B, when the second solar cell 226 of the first solar cell 224, the second solar cell 226 and the third solar cell 228 at the same row fails, the disclosure can use a laser to cut the metal trace layer in the second opening 218 for the organic photovoltaic module to bypass the failed second solar cell 226 to repair the solar cell module.

While the disclosure has been described by way of example and in terms of the preferred embodiments, it is to be understood that the disclosure is not limited to the disclosed embodiments. It is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic photovoltaic module, comprising:
a plurality of devices, wherein neighboring devices are separated by a gap, and each of the devices comprise a bottom electrode, a first carrier transporting layer, an active layer, a second carrier transporting layer and a top electrode;
an insulating layer disposed on the devices and filled into the gap, wherein the insulating layer comprises a first opening exposing the bottom electrode and a second opening exposing the top electrode; and
a metal trace layer filled into the first opening and the second opening to connect the devices in series or in parallel.

2. The organic photovoltaic module as claimed in claim 1, wherein the first carrier transporting layer and the second carrier transporting layer transport electrons or holes respectively depending on the structures of the devices.

3. The organic photovoltaic module as claimed in claim 2, wherein the electron transporting layer comprises Ca, Li, Cs₂CO₃, TiO₂, LiF or ZnO.

4. The organic photovoltaic module as claimed in claim 2, wherein the hole transporting layer comprises PEDOT:PSS, V₂O₅, MoO₃ or WO₃.

5. The organic photovoltaic module as claimed in claim 1, wherein the active layer is an organic bulk heterojunction optic electron convention layer, which is a chemical compound or a mixture comprising of an organic conjugated polymer donor material and a receptor material.

6. The organic photovoltaic module as claimed in claim 1, further comprising a protective layer on the metal trace layer and the insulating layer.

7. A method for forming an organic photovoltaic module, comprising:
providing a substrate;
forming a plurality of bottom electrodes on the substrate;
forming a first carrier transporting layer on the bottom electrodes and the substrate;
forming an active layer on the first carrier transporting layer;
forming a second carrier transporting layer on the active layer;
forming a top electrode layer on the second carrier transporting layer and patterning the top electrode layer to form a plurality of top electrodes;
performing a patterning process to the first carrier transporting layer, the active layer and the second carrier transporting layer to form a plurality of devices, wherein neighboring devices are separated by a gap;
forming an insulating layer on the device and filled into the gap, wherein the insulating layer comprises a first opening exposing the bottom electrode and a second opening exposing the top electrode; and
forming a metal trace layer to be filled into the first opening and the second opening to connect the devices in series or in parallel.

8. The method for forming an organic photovoltaic module as claimed in claim 7, wherein the first carrier transporting layer and the second carrier transporting layer transport electrons or holes respectively depending on the structures of the devices.

9. The method for forming an organic photovoltaic module as claimed in claim 8, wherein the electron transporting layer comprises Ca, Li, Cs₂CO₃, TiO₂, LiF or ZnO.

10. The method for forming an organic photovoltaic module as claimed in claim 8, wherein the hole transporting layer comprises PEDOT:PSS, V₂O₅, MoO₃ or WO₃.

11. The method for forming an organic photovoltaic module as claimed in claim 7, wherein the method for forming the first carrier transporting layer, the active layer and the second carrier transporting layer comprises spin coating, slot die coating, gravure coating or ink jet printing.

12. The method for forming an organic photovoltaic module as claimed in claim 7, wherein the patterning process comprises an etching process, lacer cutting process or mechanical dicing.

13. A method for repairing an organic photovoltaic module, comprising:
providing an organic photovoltaic module, comprising:
a plurality of devices, wherein neighboring devices are separated by a gap, and each of the devices comprise a bottom electrode, a first carrier transporting layer, an active layer, a second carrier transporting layer and a top electrode;
an insulating layer disposed on the devices and filled into the gap, wherein the insulating layer comprises a first opening exposing the bottom electrode and a second opening exposing the top electrode; and
a metal trace layer filled into the first opening and the second opening to connect the devices in series or in parallel,
wherein when one of the devices fails, a knife or laser is used to cut the metal trace layer in the first opening or the second opening of the failed device for the organic photovoltaic module to bypass the failed device to repair the organic photovoltaic module.
